(19) United States
(12) Patent Application Publication
(10) Pub. No.: US 2026/0090313 A1
(43) Pub. Date: Mar. 26, 2026

(54) CLEANING DEVICE INCLUDING LASER MARKING UNIT

(71) Applicant: Mu-tech Precision Co., Ltd., Kaohsiung City (TW)

(72) Inventors: Chih-Jen YANG, Taichung City (TW); Kuo-Chang SHIH, Pingtung County (TW); Fan-Ching CHANG, Taichung City (TW)

(73) Assignee: Mu-tech Precision Co., Ltd., Kaohsiung City (TW)

(21) Appl. No.: 19/098,360

(22) Filed: Apr. 2, 2025

(30) Foreign Application Priority Data
Sep. 26, 2024 (TW) 113136670

(51) Int. Cl. H01L 21/67

(52) U.S. Cl. CPC H10P 72/0414; H10P 72/0604

(57) ABSTRACT

A cleaning device includes a base unit adapted to support a wafer and a drive unit disposed above the base unit. The drive unit includes a left-right mount, a left-right slide seat slidably disposed on the left-right mount, a top-bottom mount fixed to the left-right slide seat, a top-bottom slide seat slidably disposed on the top-bottom mount, and a carry plate fixed to the top-bottom slide seat. A nozzle seat is connected to the carry plate. A nozzle is connected to the nozzle seat to spray a cleaning solution onto the wafer. A laser marking unit is connected to the left-right mount to project laser lights to the cleaning solution sprayed onto the wafer.

### CROSS-REFERENCE TO RELATED APPLICATION

This application claims priority to Taiwanese Invention Patent Application No. 113136670, filed on Sep. 26, 2024, the entire disclosure of which is incorporated by reference herein.

### FIELD

The disclosure relates to a cleaning device, and more particularly to a cleaning device including a laser marking unit.

### BACKGROUND

With development of wafer packaging technology, electric components on a wafer surface are increasingly precise. The electric components are easily damaged by contaminants such as dust and small particles attached to them. To remove the contaminants, wafer cleaning is required using an existing cleaning device.

However, in general, a transparent cleaning solution is used to clean the wafer. When cleaning the wafer using the existing cleaning device, it is difficult for an operator to see whether the wafer is being cleaned according to a predetermined path. There is room for improvement on the existing cleaning device.

### SUMMARY

Therefore, an object of the disclosure is to provide a cleaning device that can alleviate at least one of the drawbacks of the prior art.

According to the disclosure, a cleaning device is adapted to clean a wafer. The cleaning device includes a base unit, a drive unit, a nozzle unit, and a laser marking unit.

The base unit is adapted to support the wafer thereon.

The drive unit is disposed above the base unit, and includes a left-right mount, a left-right slide seat, a top-bottom mount, a top-bottom slide seat, and a carry plate. The left-right slide seat is disposed on the left-right mount and is slidable relative to the left-right mount in a left-right direction. The top-bottom mount is fixed to the left-right slide seat. The top-bottom slide seat is disposed on the top-bottom mount and is slidable relative to the top-bottom mount in a top-bottom direction perpendicular to the left-right direction. The carry plate is fixed to the top-bottom slide seat.

The nozzle unit includes a nozzle seat and at least one nozzle. The nozzle seat is connected to a bottom end of the carry plate. The at least one nozzle is connected to the nozzle seat and is adapted to spray a cleaning solution onto the wafer.

The laser marking unit is connected to the left-right mount and is adapted to project laser lights to the cleaning solution sprayed on the wafer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an embodiment of a cleaning device according to the disclosure.

FIG. 2 is another perspective view of the embodiment illustrating the cleaning device.

FIG. 3 is a fragmentary perspective view of the embodiment illustrating a carry plate, a nozzle unit, and an image-capture unit.

FIG. 4 is a top view of the embodiment illustrating the cleaning device.

FIG. 5 is a side view taken along line V-V of FIG. 4.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

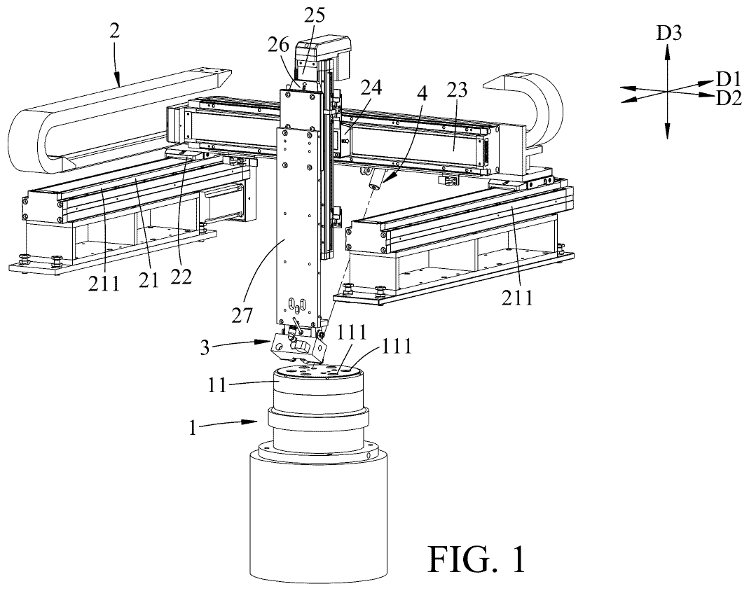

Referring to FIGS. 1 to 3, a cleaning device according to an embodiment of the disclosure is adapted to clean a wafer 9. The cleaning device includes a base unit 1, a drive unit 2, a nozzle unit 3, a laser marking unit 4, and an image-capture unit 5. The base unit 1 is adapted to support the wafer 9 thereon, and includes a base seat 11 that defines six openings 111, and six vacuum sucking members (not shown) that are respectively disposed in the openings 111. The vacuum sucking members are adapted to attract and position the wafer 9 onto the base seat 11 in a vacuumed manner. A quantity of the openings 111 and a quantity of the vacuum sucking members may vary depending on requirements.

The drive unit 2 is disposed above the base unit 1, and includes a front-rear mount subunit 21, a front-rear slide seat 22, a left-right mount 23, a left-right slide seat 24, a top-bottom mount 25, a top-bottom slide seat 26, and a carry plate 27. The front-rear slide seat 22 is disposed on the front-rear mount subunit 21 and is slidable relative to the front-rear mount subunit 21 in a front-rear direction (D1). The left-right mount 23 is fixed to the front-rear slide seat 22. The left-right slide seat 24 is disposed on the left-right mount 23 and is slidable relative to the left-right mount 23 in a left-right direction (D2) perpendicular to the front-rear direction (D1). The top-bottom mount 25 is fixed to the left-right slide seat 24. The top-bottom slide seat 26 is disposed on the top-bottom mount 25 and is slidable relative to the top-bottom mount 25 in a top-bottom direction (D3) perpendicular to the front-rear direction (D1) and the left-right direction (D2). The carry plate 27 is fixed to the top-bottom slide seat 26.

In this embodiment, the front-rear mount subunit 21 includes two front-rear mounts 211 that are spaced apart from each other in the left-right direction (D2). The front-rear slide seat 22 is disposed between the front-rear mounts 21s and is slidable relative to the front-rear mounts 211.

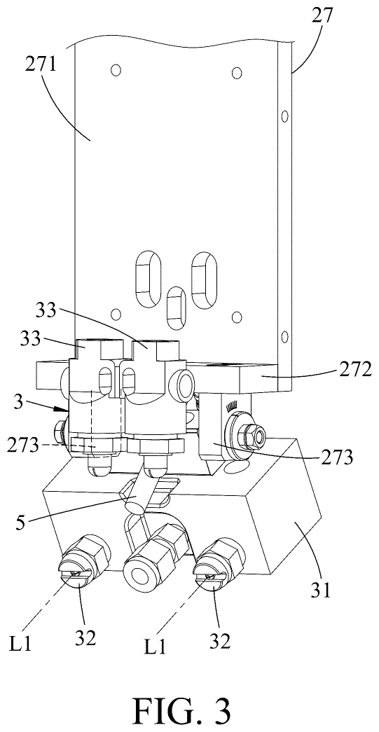

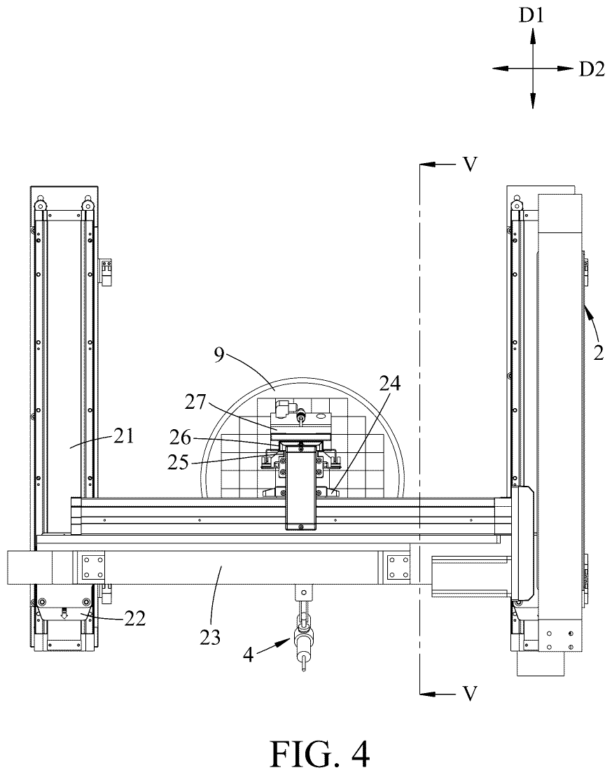

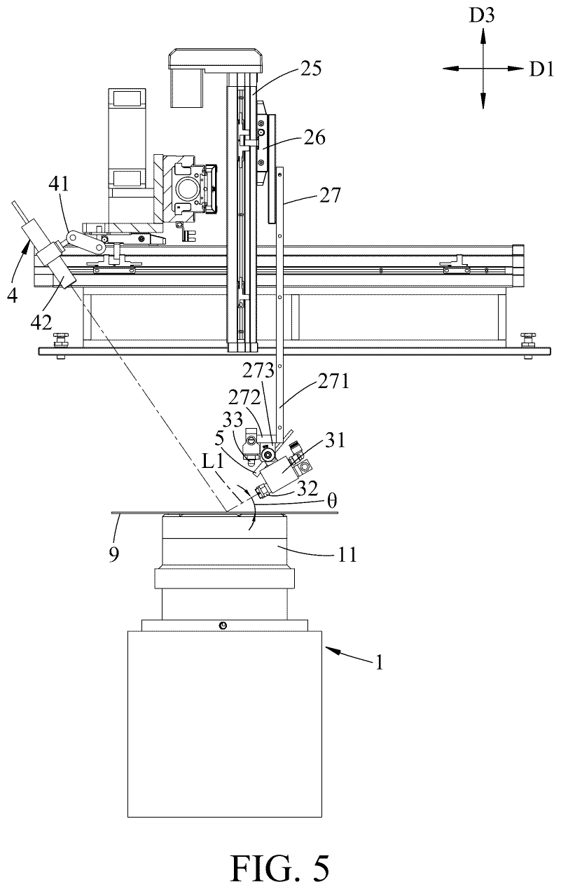

Referring to FIGS. 4 and 5 in combination with FIG. 3, the carry plate 27 has a main plate portion 271, a bottom plate portion 272, and two spaced-apart extension portions 273. The main plate portion 271 has a bottom end serving as a bottom end of the carry plate 27. The bottom plate portion 272 is connected to the bottom end of the main plate portion 271 and is elongated in the front-rear direction (D1). The extension portions 273 are spaced-apart from each other in left-right direction (D2) and extend downwardly from the bottom plate portion 272.

The nozzle unit 3 includes a nozzle seat 31, two nozzles 32, and two auxiliary nozzles 33. In this embodiment, the auxiliary nozzles 33 are fixed to the bottom plate portion 272 of the carry plate 27 and are adapted to spray a cleaning solution onto the wafer 9. Each of the nozzles 32 and each of the auxiliary nozzles 33 is a fan-shaped nozzle. In other embodiments, each of the nozzles 32 and each of the auxiliary nozzles 33 may be a conical nozzle, a straight nozzle, or an atomizing nozzle.

The nozzle seat 31 is rotatably connected to bottom ends of the extension portions 273 in an upward and downward manner. A soft conduit (not show) is connected to and conveys a cleaning solution to the nozzle seat 31. The cleaning solution is adapted for cleaning the wafer 9.

The nozzles 32 are connected to the nozzle seat 31, and each of the nozzles 32 is adapted to receive the cleaning solution from the nozzle seat 31 and spray the cleaning solution onto the wafer 9.

In this embodiment, the cleaning solution is a Standard Clean-1 (SC-1) solution, a Standard Clean-2 (SC-2) solution, or another chemical cleaning solution.

Each of the nozzles 32 extends along an axis (L1). The axis (L1) is adapted to cooperate with the wafer 9 to form an included angle (θ) therebetween. As shown in FIG. 5, the included angle (θ) of each of the nozzles 32 is adjustable by rotating the nozzle seat 31 relative to the carry plate 27 to facilitate cleaning of gaps formed on the wafer 9.

It should be noted that a quantity of the nozzles 32 and a quantity of the auxiliary nozzles 33 are not limited hereto. In other embodiments, a quantity of the nozzles 32 and a quantity of the auxiliary nozzles 33 may be one or greater than two.

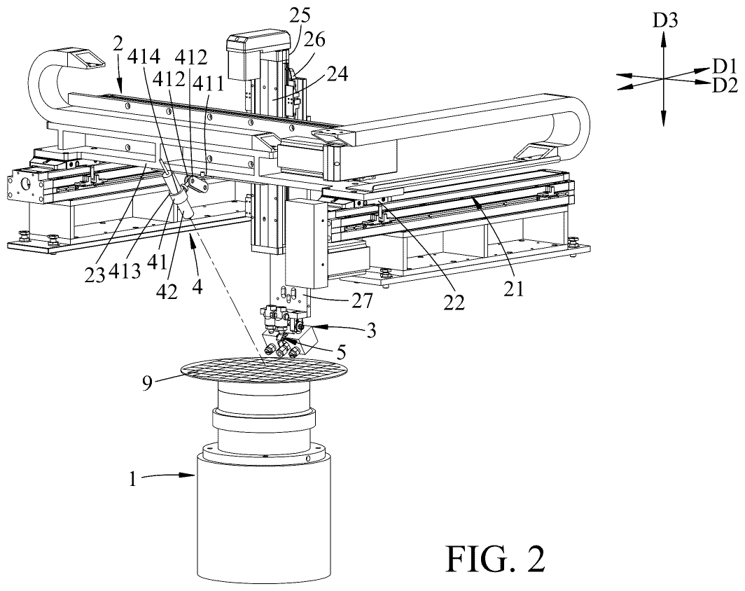

Referring back to FIGS. 2, 4, and 5, the laser marking unit 4 is connected to the left-right mount 23. In this embodiment, the laser unit 4 includes a laser mount 41 and a laser emitter 42.

The laser mount 41 has a fixed portion 411, two connection portions 412, and a mount portion 413. The fixed portion 411 is fixed to the left-right mount 23. The connection portions 412 are rotatably connected to the fixed portion 411 and are spaced apart from each other in the left-right direction (D2). The mount portion 413 is rotatably connected to the connection portions 412, is opposite to the fixed portion 411, and defines a mount hole 414. Specifically, when the connection portions 412 are rotated relative to the fixed portion 411 to a predetermined position, the mount portion 413 is operable to be immobilized relative to the left-right mount 23.

The laser emitter 42 extends through the mount hole 414 and is fixed to the mount portion 413. In this embodiment, the laser emitter 42 is a red laser diode.

The laser marking unit 4 is adapted to project laser lights to the cleaning solutions sprayed from the nozzles 32 onto the wafer 9 for on-site inspections carried out by an operator.

The image-capture unit 5 is fixed to the nozzle unit 3, and is adapted to generate sequential pictures of the wafer 9 cleaned using the cleaning solutions from the nozzles 32. The sequential pictures of the wafer 9 cleaned using the cleaning solutions from the nozzles 32 allow the operator to inspect a cleaning process of the wafer 9 after the cleaning process is completed.

In use, the laser lights from the laser marking unit 4 projected onto the cleaning solutions sprayed from the nozzles 32 allow the operator to perform on-site inspection of the cleaning process of the wafer 9 or after the cleaning process is completed.

In summary, the cleaning device of the disclosure has the following advantages.

Because the left-right mount 23 is fixed to the front-rear slide seat 22 that is slidable relative to the front-rear mount subunit 21 in the front-rear direction (D1), and because the nozzle seat 31 is connected to the carry plate 27 that is connected to the left-right mount 23 to move together with the front-rear slide seat 22, the nozzles 32 connected to the nozzle seat 31 and the laser marking unit 4 connected to the left-right mount 23 are simultaneously movable together with each other in the front-rear direction (D1). By virtue of the laser marking unit 4 and the nozzles 32 being simultaneously movable together with each other in the front-rear direction (D1), it is easier to inspect the cleaning process of the wafer 9 through the laser marking unit 4 projecting laser lights onto the cleaning solutions sprayed from the nozzles 32 onto the wafer 9.

By virtue of the image-capture unit 5 generating the sequential pictures of the wafer 9 cleaned using the cleaning solutions from the nozzles 32, the operator may inspect the cleaning process of the wafer 9 after the cleaning process is completed.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A cleaning device adapted to clean a wafer, said cleaning device comprising:
a base unit adapted to support the wafer thereon;
a drive unit disposed above said base unit, and including
a left-right mount,
a left-right slide seat that is disposed on said left-right mount and that is slidable relative to said left-right mount in a left-right direction,
a top-bottom mount that is fixed to said left-right slide seat,
a top-bottom slide seat that is disposed on said top-bottom mount and that is slidable relative to said top-bottom mount in a top-bottom direction perpendicular to the left-right direction, and
a carry plate that is fixed to said top-bottom slide seat;
a nozzle unit including
a nozzle seat that is connected to a bottom end of said carry plate, and
at least one nozzle that is connected to said nozzle seat and that is adapted to spray a cleaning solution onto the wafer; and
a laser marking unit connected to said left-right mount and adapted to project laser lights to the cleaning solution sprayed onto the wafer.

2. The cleaning device as claimed in claim 1, further comprising an image-capture unit fixed to said nozzle unit, and adapted to generate sequential pictures of the wafer cleaned by the cleaning solution from said at least one nozzle.

3. The cleaning device as claimed in claim 1, wherein said base unit includes a base seat that defines a plurality of openings.

4. The cleaning device as claimed in claim 1, wherein:
said drive unit further includes a front-rear mount subunit, and a front-rear slide seat that is disposed on said front-rear mount subunit and that is slidable relative to said front-rear mount subunit in a front-rear direction perpendicular to the left-right direction and the top-bottom direction; and
said left-right mount is fixed to said front-rear slide seat.

5. The cleaning device as claimed in claim 1, wherein:
said carry plate has
a main plate portion that has a bottom end serving as said bottom end of said carry plate,
a bottom plate portion that is connected to said bottom end of said main plate portion, and
two spaced-apart extension portions that extend downwardly from said bottom plate portion;
said nozzle seat is rotatably connected to bottom ends of said extension portions; and
said at least one nozzle extends along an axis, said axis being adapted to cooperate with the wafer to form an included angle therebetween.

6. The cleaning device as claimed in claim 5, wherein said nozzle unit further includes at least one auxiliary nozzle that is fixed to said bottom plate portion of said carry plate and that is adapted to spray the cleaning solution onto the wafer.

7. The cleaning device as claimed in claim 1, wherein said laser marking unit includes
a laser mount having
a fixed portion that is fixed to said left-right mount,
two connection portions that are rotatably connected to said fixed portion, and
a mount portion that is rotatably connected to said connection portions, that is opposite to said fixed portion, and that defines a mount hole; and
a laser emitter extending through said mount hole and fixed to said mount portion.
